(19) United States
(12) Patent Application Publication
(10) Pub. No.: US 2019/0159336 A1
(43) Pub. Date: May 23, 2019

(54) METHOD OF FABRICATING STRAIN-PRESSURE COMPLEX SENSOR AND SENSOR FABRICATED THEREBY

(71) Applicant: ELECTRONICS AND TELECOMMUNICATIONS RESEARCH INSTITUTE, Daejeon (KR)

(72) Inventors: Seong Jun KIM, Daejeon (KR); Choon Gi CHOI, Daejeon (KR)

(21) Appl. No.: 16/189,020

(22) Filed: Nov. 13, 2018

(30) Foreign Application Priority Data
Nov. 17, 2017 (KR) 10-2017-0154276
Jan. 29, 2018 (KR) 10-2018-0010961

(51) Int. Cl. H05K 1/02; H05K 3/36

(52) U.S. Cl. CPC H05K 1/0283; H05K 2203/0568; H05K 2201/10151; H05K 3/361

(57) ABSTRACT

Provided is a method for fabricating a strain-pressure complex sensor and a sensor fabricated thereby. This method includes coating a fabric with a graphene oxide; reducing the graphene oxide coated with the fabric to form a graphene; disposing carbon nanotubes on the fabric coated with the graphene; and connecting an electrode to the fabric.

### CROSS-REFERENCE TO RELATED APPLICATIONS

This U.S. non-provisional patent application claims priority under 35 U.S.C. § 119 of Korean Patent Application Nos. 10-2017-0154276, filed on Nov. 17, 2017, and 10-2018-0010961, filed on Jan. 29, 2018, the entire contents of which are hereby incorporated by reference.

### BACKGROUND

The present disclosure herein relates to a method of fabricating a strain-pressure complex sensor and a sensor fabricated thereby.

When an object is stretched or compressed, a strain of the length occurs in the object. A strain sensor refers to a sensor which utilizes the change of electric resistance while the strain of such length occurs. When the external force is applied, if the original length (L) of an object is increased the cross-sectional area (A) is decreased, the electrical resistance is increases, and on the contrary, if the length is decreased, the electrical resistance is decreased. The strain sensor using this piezoresistive effect is called a piezoresistive sensor.

R=ρ*L/A [Equation 1]

In Equation 1, R indicates electrical resistance, ρ is an inherent resistance determined by the property of a conductor. The sensor that makes it possible to measure the degree of surface change of wearing objects from the change in electrical resistance by applying such a method to a conductive fabric material is a fabric-based strain sensor.

These fabric-based strain sensors are, according to the structures thereof, classified into a positive piezoresistive sensor in which when strain is applied to the outside and thus the length is increased, the electrical resistance is increased and when the strain is removed, the resistance is decreased, and in contrast, a negative piezoresistive sensor in which when a tensile force is applied and thus the length is increased, the electrical resistance is increased, and when the length is decreased, the resistance is decreased.

### SUMMARY

The present disclosure provides a method of fabricating a strain-pressure complex sensor which has a simple and easy fabricating process.

The present disclosure also provides a strain-pressure complex sensor having excellent reproducibility and waterproofness.

An embodiment of the inventive concept provides a method for fabricating a strain-pressure complex sensor comprising: coating a fabric with a graphene oxide; reducing the graphene oxide coated on the fabric to form a graphene; disposing carbon nanotubes on the fabric coated with the graphene; and connecting an electrode to the fabric.

In an embodiment, the coating of the fabric with the graphene oxide may include immersing the fabric in a first solution containing the graphene oxide; and drying the fabric.

In an embodiment, the first solution may include water.

In an embodiment, the reducing of the graphene oxide coated on the fabric may include exposing the fabric coated with the graphene oxide to vapor of a reducing agent.

In an embodiment, the reducing agent may be hydrazine.

In an embodiment, the exposing of the fabric coated with the graphene oxide to the vapor of the reducing agent may be performed in a sealed chamber at a temperature of 70-80° C.

In an embodiment, the disposing of the carbon nanotubes on the fabric coated with the graphene may include immersing the fabric coated with the graphene in a second solution containing carbon nanotubes; and drying the fabric.

In an embodiment, the second solution may include at least one of dimethylformamide (DMF) and dichlorobenzene (DCB).

In an embodiment, in the second solution, the carbon nanotubes may be contained in an amount of 0.01-0.04 wt %.

In an embodiment, the fabric may be cotton or wool.

In an embodiment, the method, after the connecting of the electrode to the fabric, may further include performing a test, wherein the performing of a test may repeat several times at least one of: applying a tensile force to the fabric and then stopping; applying a compressive force to the fabric and then stopping; and immersing the fabric in water and drying.

In an embodiment of the inventive concept, a strain-pressure complex sensor includes a fabric; a graphene coated on the fabric; and carbon nanotubes disposed on the fabric coated with the graphene, and senses a tensile force and a compressive force.

In an embodiment, the strain-pressure complex sensor may further include a first electrode connected to one end of the fabric; and a second electrode connected to the other end of the fabric.

In an embodiment, the graphene may be a reduced graphene oxide. A part of the graphene may be combined with oxygen.

### BRIEF DESCRIPTION OF THE FIGURES

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIG. 1 is a flowchart illustrating a fabricating process of a strain-pressure complex sensor, according to embodiments of the inventive concept;

FIGS. 2 to 6 are views sequentially illustrating a fabricating process of a strain-pressure complex sensor, according to embodiments of the inventive concept;

FIGS. 7A, 7B, 8A, 8B and 9B are graphs showing experimental results of a strain-pressure complex sensor, according to embodiments of the inventive concept; and

FIG. 9A shows photos of a strain-pressure complex sensor obtained as a result of experiments, according to embodiments of the inventive concept.

### DETAILED DESCRIPTION

The above objects, other objects, features and advantages of the present invention will be more readily understood from the following preferred embodiments with reference to the accompanying drawings. However, the present invention is not limited to the embodiments described herein but may be embodied in other forms. Rather, the embodiments disclosed herein are being provided so that this disclosure will be thorough and complete, and will fully convey the concept of the invention to those skilled in the art.

In this specification, when an element is referred to as being on another element, it may be directly formed on another element, or a third element may be interposed therebetween. Further, in the drawings, the thickness of the components is exaggerated for an effective description of the technical content.

The embodiments described herein will be described with reference to cross-sectional views and/or plan views that are ideal illustrations of the present invention. In the drawings, the thicknesses of the films and regions are exaggerated for an effective explanation of the technical content. Thus, the shape of the illustrations may be modified by manufacturing techniques and/or tolerances. Accordingly, the embodiments of the present invention are not limited to the specific forms shown, but also include changes in the shapes that are produced according to the manufacturing process. For example, the etching regions shown at right angles may be rounded or may have a shape with a certain curvature. Thus, the regions illustrated in the figures have attributes, and the shapes of the regions illustrated in the figures are intended to illustrate specific types of regions of the elements and are not intended to limit the scope of the invention. Although the terms first, second, etc. in various embodiments of the present disclosure are used to describe various components, these components should not be limited by these terms. These terms have only been used to distinguish one element from another. The embodiments described and exemplified herein also include their complementary embodiments.

The terminology used herein is for the purpose of illustrating embodiments and is not intended to be limiting of the present invention. In this specification, singular forms include plural forms unless the context clearly dictates otherwise. The terms “comprise” and/or “comprising” used in the specification do not exclude the presence or addition of one or more other elements.

Hereinafter, exemplary embodiments of the inventive concept will be described in detail with reference to the accompanying drawings.

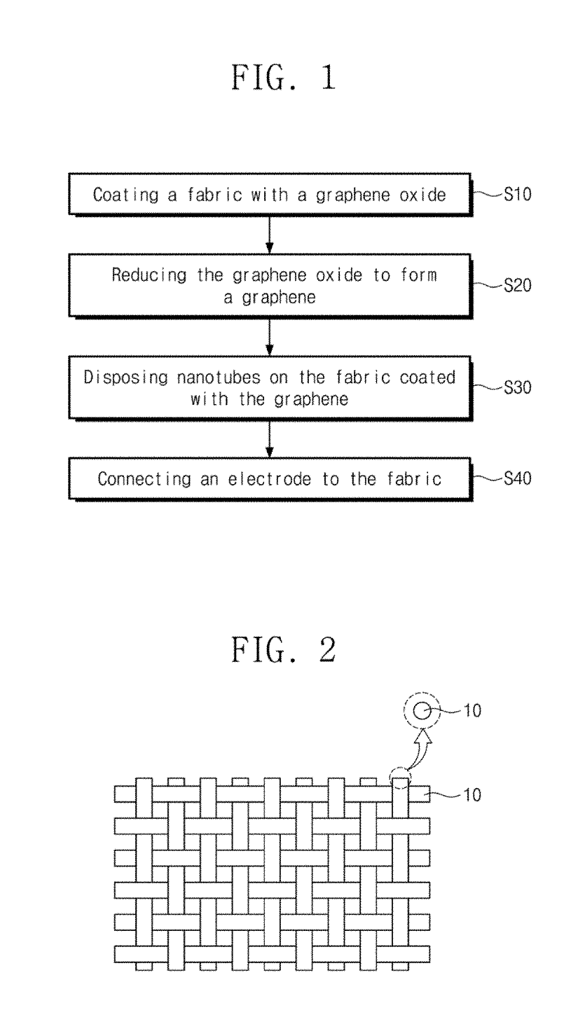

FIG. 1 is a flowchart illustrating a fabricating process of a strain-pressure complex sensor, according to embodiments of the inventive concept. FIGS. 2 to 6 are views sequentially illustrating a fabricating process of a strain-pressure complex sensor, according to embodiments of the inventive concept. In FIGS. 2 to 6, a cross sectional view of a part of each fabric is illustrated in a dash line circle.

Referring to FIGS. 1 and 2, in a method of fabricating a strain-pressure complex sensor according to embodiments of the inventive concept, a fabric 10 is first prepared. The fabric 10 may be, for example, cotton or wool. The fabric 10 may be a fiber product in which weft yarns and warp yarns are crossed. The fabric 10 may be stretched and contracted in a transversal direction, a longitudinal direction, a diagonal direction, or the like. The fabric 10 may be dried after rinsing several times with deionized water in order to remove chemical components and impurities which may be present on the surface thereof.

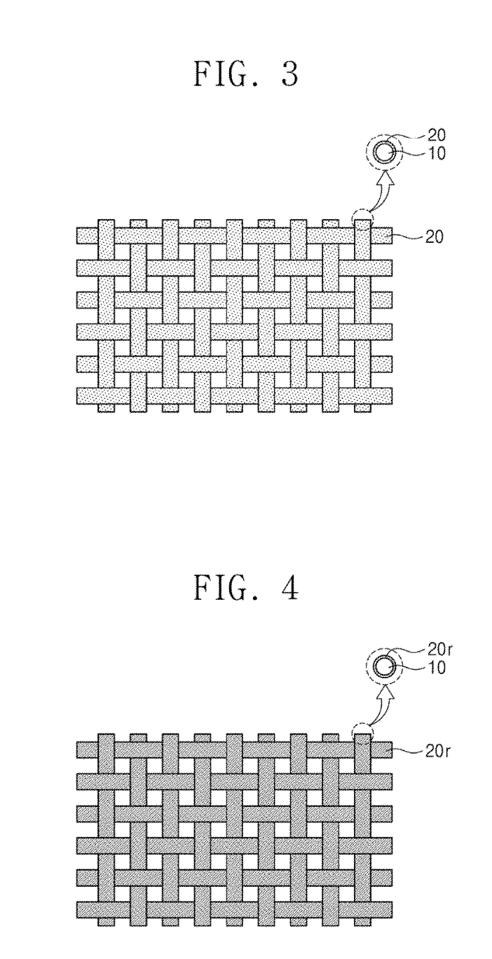

Referring to FIGS. 1 and 3, the fabric 10 may be coated with a graphene oxide 20 (S10). The coating of the fabric 10 with the graphene oxide 20 may include immersing the fabric 10 in a first solution containing the graphene oxide 20; and drying the fabric 10. The first solution may include water. Graphene has very excellent electric conductivity and flexibility, but it is difficult to separate the graphene from graphite. However, when graphite is oxidized, a graphene oxide may be readily obtained by repelling each layer. After obtaining the graphene oxide so easily, the graphene oxide is mixed with water to form a first solution, and when the fabric 10 is immersed in the first solution and then dried, the graphene oxide 20 may be easily coated on the fabric 10. The first solution may include a graphene oxide, for example, at a concentration of 3 mg/ml. Immersing in the first solution may be performed, for example, for about 1 to 30 minutes.

Referring to FIGS. 1 and 4, the graphene oxide 20 coated on the fabric 10 may be reduced to form graphene 20r (S20). The graphene 20r may also be referred to as a reduced graphene oxide. Depending on the degree of reduction (when the reduction is not perfect), some of the graphene 20r may remain in an oxygen-bonded state. The reducing S20 of the graphene 20 coated on the fabric 10 may include exposing the fabric 10 coated with the graphene oxide 20 to the vapor of a reducing agent. The reducing agent may be, for example, hydrazine. The exposing of the fabric 10 coated with the graphene oxide 20 to the vapor of the reducing agent may be performed in a sealed chamber, for example for 10 to 30 hours, at a temperature of 70-80° C.

Referring to FIGS. 1 and 5, carbon nanotubes 30 may be disposed on the fabric coated with the graphene 20r (S30). The disposing S30 of carbon nanotubes 30 on the fabric 10 coated with the graphene 20r may include immersing the fabric 10 coated with the graphene 20r in a second solution containing carbon nanotubes; and drying the fabric 10. The second solution may include at least one of dimethylformamide (DMF) and dichlorobenzene (DCB). In the second solution, the carbon nanotubes may be included in an amount of 0.01-0.04 wt %.

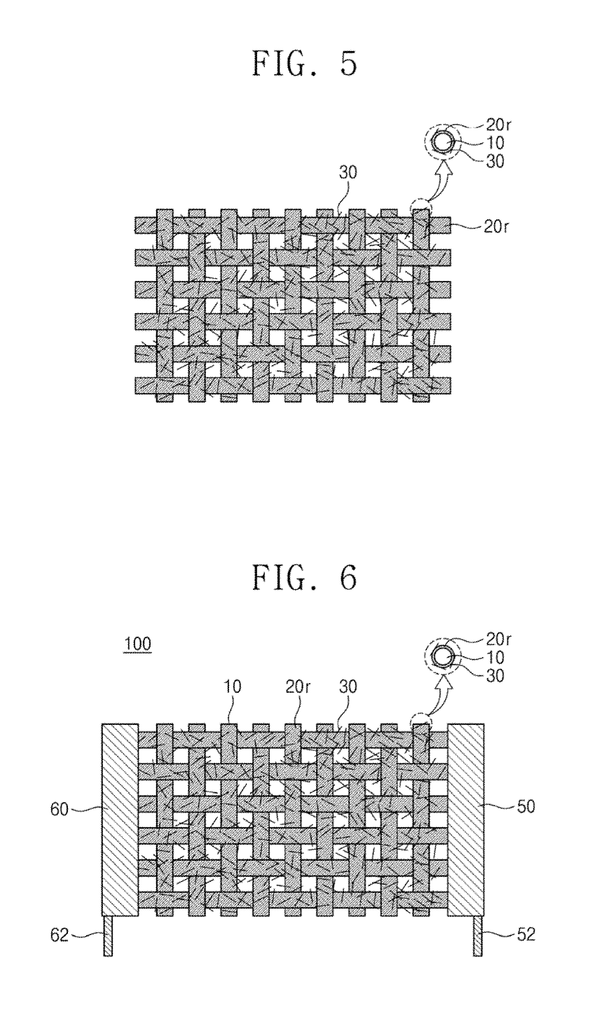

Referring to FIGS. 1 and 6, a first electrode 50 may be connected to one end of the fabric 10, and a second electrode 60 may be connected to the other end of the fabric 10 (S40). A first wiring 52 may be connected to the first electrode 50, and a second wiring 62 may be connected to the second electrode 60. As a result, a strain-pressure complex sensor 100 may be formed. The strain-pressure complex sensor 100 may sense a tensile force and a compressive force. In the strain-pressure complex sensor 100, physical damages such as breaking or peeling which may occur on an interface between graphene and fabric when the tensile force and the compressive force are repeatedly applied, are cured by connecting carbon nanotubes having complex random network structures, thereby capable of minimizing the degradation of element characteristics. In addition, the electrical conductivity may be increased through an increase in the amount of carbon nanotubes. In addition, due to the hydrophobic nature of graphene and carbon nanotubes, there is an advantage that washing is easy when elements are applied to cloths.

As described above, after the strain-pressure complex sensor 100 is formed, the method may further include performing a test of the strain-pressure complex sensor 100. The performing of a test may repeat several times at least one of applying a tensile force to the fabric 10 and then stopping; applying a compressive force to the fabric 10 and then stopping; and immersing the fabric 10 in water and drying.

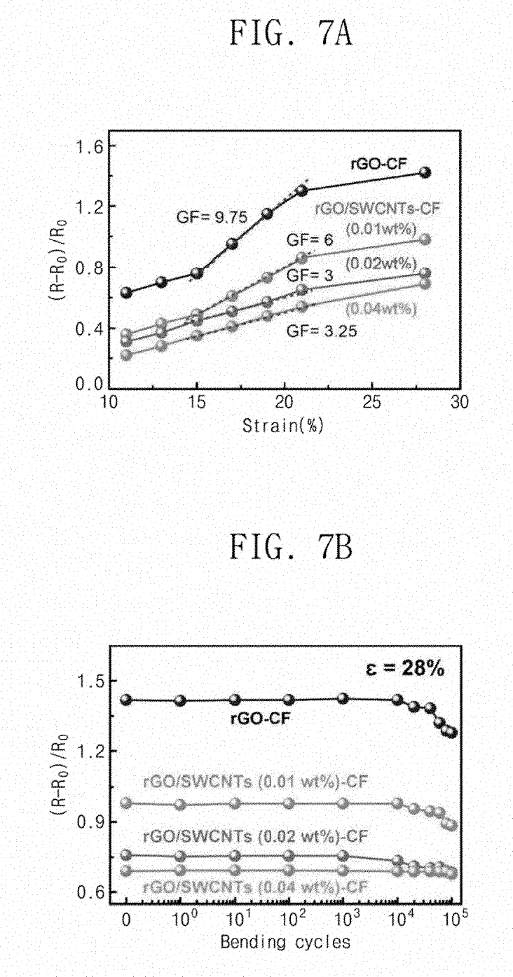

FIGS. 7A, 7B, 8A, 8B, and 9B are graphs showing experimental results of a strain-pressure complex sensor, according to embodiments of the inventive concept.

Referring to FIGS. 7A, 7B, 8A, 8B and 9B, in Experiment Examples of the inventive concept, strain-pressure complex sensors were fabricated through a process described with reference to FIGS. 1 to 6. In Experimental Examples 1 to 3, second solutions containing carbon nanotubes were prepared such that the carbon nanotubes were included in an amount of 0.01 wt %, 0.02 wt %, and 0.04 wt %, respectively. In a sensor fabricated as a control group, the first and second electrodes 50 and 60 were connected in the state of FIG. 4 in which carbon nanotubes were not disposed on the fabric 10.

As an index for evaluating the performance of a strain sensor, a gauge factor (GF) may be used. This gauge factor is an important parameter determining the sensitivity of a sensor. When an original length L₀ is varied by ΔL by an external force applied to the fiber, the length strain ΔL/L₀ is defined as ε (strain value), and the gauge factor (GF) may be expressed by Equation 2, according to Equation 1.

GF=(ΔR/R₀)/(ΔL/L₀)=ΔR/εR₀ Equation 2

FIG. 7 is a graph showing a resistance change rate (longitudinal axis, that is, corresponding to ΔR/R₀) according to strain (horizontal axis, that is, corresponding to ε) while repeating the application and removal of a tensile force by bending each of the strain-pressure complex sensors fabricated as described above. In FIG. 7A, CF refers to a cotton fabric. rGO refers to an oxidized graphene oxide. SWCNTs refer to single-walled carbon nanotubes. Here, a single-walled carbon nanotube refers to a carbon nanotube in which a wall composed of carbon atoms does not exist in multiple layers but exists as a single tube. The graph marked by rGO-CF at the top in FIG. 7A is for a control group sensor in which carbon nanotubes are not disposed. The graph marked by (0.04 wt %) at the lowermost position in FIG. 7A is for a strain-pressure complex sensor according to Experimental Example 3 fabricated by using the second solution containing carbon nanotubes in an amount of 0.04 wt %. Referring to FIG. 7A, the resistance change rate becomes small as the content of carbon nanotubes increases as a whole. When the gauge ratio (GF), which is the slope value of graphs, is calculated by using these graphs, the gauge ratio of the control group without carbon nanotubes is 9.75 which is the largest value, and the gauge ratio of Experimental Examples 2 and 3 with high carbon nanotube content are relatively low 3 to 3.25, in a region where a strain value is about 15-21%. Especially, in Experimental Example 3 which is the graph marked by (0.04 wt %), it may be seen that the graph shows a constant linearity and exhibits excellent reproducibility in a region where the strain value is about 11-28%.

In FIG. 7B, while repeatedly applying and then removing the tensile force by bending the sensors fabricated in the same Experimental Examples 1 to 3 and control group as FIG. 7A, the resistance change rate depending on bending cycles is measured. In this case, strain (corresponding to ε) is fixed to 28%. Referring to FIG. 7B, it may be seen that the resistance change rate is constant as the amount of carbon nanotube is increased. For example, the strain-pressure complex sensor of Experimental Example 3, which is the graph marked (0.04 wt %), exhibits a constant resistance change rate even when bending is repeated 100,000 times, so that it can be seen that there is no degradation of element characteristics. Thus, it can be seen that the strain-pressure complex sensor according to the inventive concept exhibits excellent reproducibility.

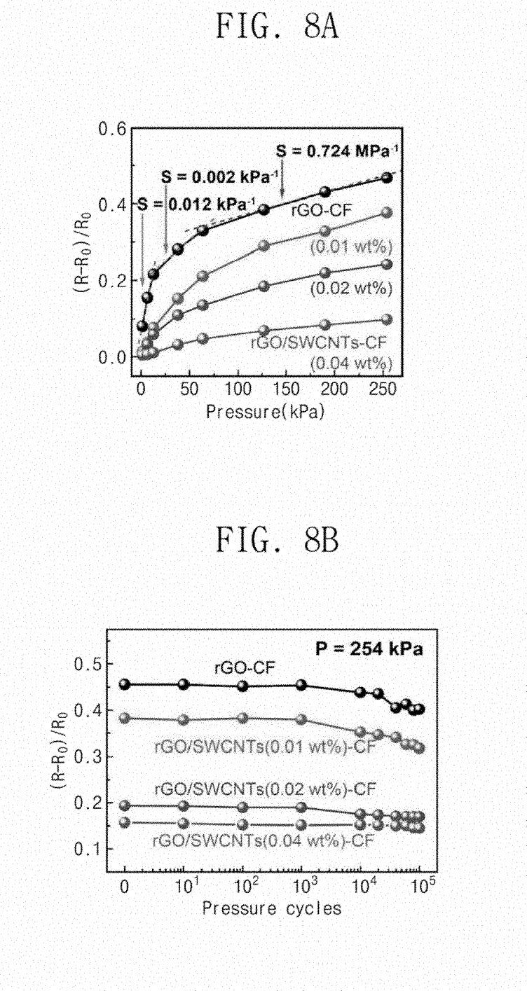

FIG. 8A is a graph measuring the resistance change rate with changing the pressing pressure while repeatedly applying and then removing the compressive force by pressing the sensors fabricated in the same Experimental Examples 1 to 3 as those of FIG. 7A, and control group. In FIG. 8A, ‘S’ represents sensitivity and may correspond to a slope in a specific region of the graph. This pressure sensitivity is an important parameter for determining the sensitivity of the sensor. When pressure P is applied to the fiber, the pressure sensitivity may be represented by Equation 3 according to Equation 1 with a relative resistance change rate (ΔR/R₀).

S=(ΔR/R₀)/ΔP [Equation 3]

Referring to FIG. 8A, it can be seen that the linearity of the graph becomes good as the amount of carbon nanotubes is increased. Further, it can be seen that the sensors of the inventive concept may be operated in the extensive pressure measurement range of about 1.27-254 kPa. In the case of Experimental Example 3, which is a graph marked by (0.04 wt %), it can be seen that constant linearity is exhibited depending on the pressure to exhibit excellent reproducibility.

FIG. 8B is a graph showing the resistance change rate depending on a pressure cycles while repeatedly applying and then removing the compressive force by pressing the sensors fabricated in the same Experimental Examples 1 to 3 as those of FIG. 7A and control group. Referring to FIG. 7B, the resistance change rate becomes small as the amount of carbon nanotubes is increased. It can be also seen that the resistance change rate according to pressure cycles becomes constant as the amount of carbon nanotubes is increased. For example, the strain-pressure complex sensor of Experimental Example 3, which is the graph marked by (0.04 wt %), exhibits a constant resistance change rate without degrading the function of the sensor even with applying a repeated compressive force of 100,000 times. Thus, it can be seen that the strain-pressure complex sensor according to the inventive concept exhibits excellent reproducibility.

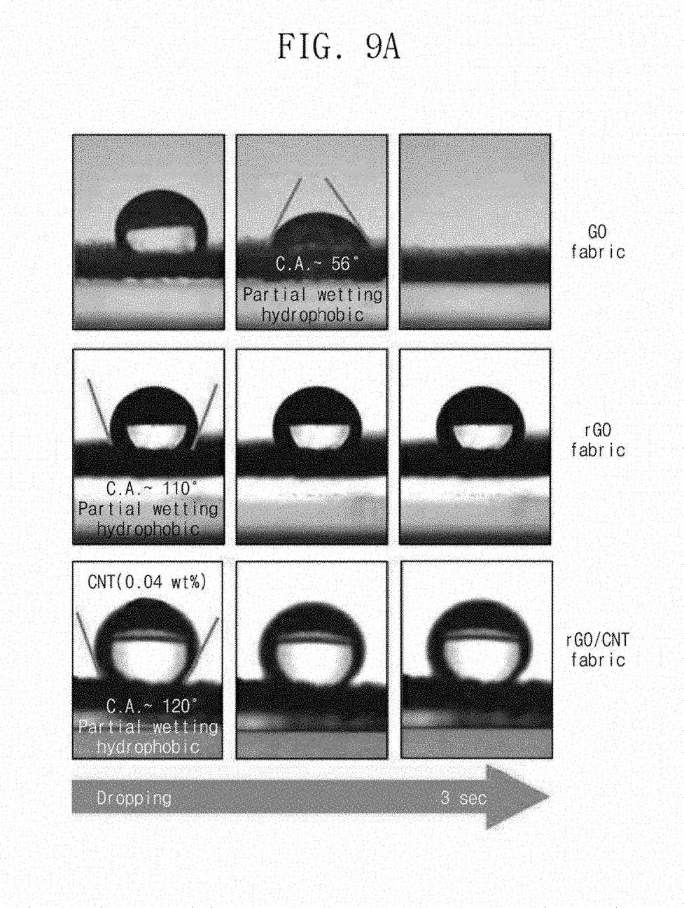

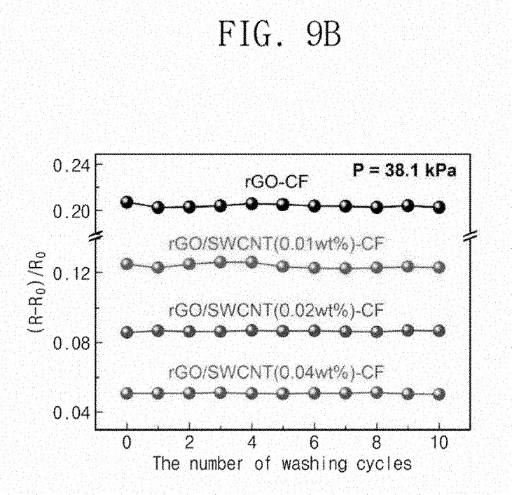

In FIG. 9A, the hydrophobicity of the strain-pressure complex sensor was tested. First, the cotton fabric of FIG. 3 (Control Group 1, GO fabric) coated with a graphene oxide before reduction, the cotton fabric of FIG. 4 (Control Group 2, rGO fabric) coated with a reduced graphene oxide, and the cotton fabric of FIG. 5 (Experimental Example 4, rGO/CNT fabric) fabricated using a second solution containing 0.04 wt % of carbon nanotubes were prepared, respectively. The shape of water droplets with time after dropping a drop of water on each cotton fabric is shown in FIG. 9A. It can be seen that in Control Group 1 (GO fabric), the water droplet disappeared after 3 seconds, and the surface of the cotton fabric coated with the graphene oxide of Control Group 1 was hydrophilic. In Control Group 1 and Example 4, it can be seen that both are hydrophobic from water droplets keeping the shapes even after 3 seconds. However, in Control Group 1, the contact angle of the water droplet to the cotton fabric surface is about 110°, which is less than about 120° of the contact angle of Experimental Example 4. As a result, it can be seen that the hydrophobicity is the highest in Experimental Example 4. Thus, it can be seen that the waterproof property is excellent.

In FIG. 9B, the resistance change rate of the sensors (Control Group, Experimental Examples 1 to 3) fabricated with reference to FIG. 7A according to the number of washing cycles was examined. To this end, the sensors (Control Group, Experimental Examples 1 to 3) were each wetted with water for 10 minutes, then dried, and the compressive force was applied to and released from the sensors. While the procedure was repeated 10 times for each, the resistance change rate depending on the number of washing cycles is shown in FIG. 9B. At this time, the pressure for applying the compressive force was about 38.1 kPa. Referring to FIG. 9B, it can be seen that the resistance change rate depending on the number of washing cycles becomes constant as the amount of carbon nanotubes is increased. Thus, it can be seen that the strain-pressure complex sensor according to the inventive concept exhibits excellent reproducibility.

The strain-pressure complex sensor and the method of fabricating the same according to embodiments of the inventive concept may be easily applied to ordinary clothes, gloves, seat sheets, etc. to detect blood pressure, heart rate, body movement, body posture, etc., so that it can be applied to various industrial fields such as health care, beds, clothing, chairs, and automotive.

A method for fabricating a strain-pressure complex sensor according to embodiments of the inventive concept has a simple and easy fabricating process.

A method for fabricating a strain-pressure complex sensor according to embodiments of the inventive concept is excellent in reproducibility and waterproofness.

What is claimed is:

1. A method for fabricating a strain-pressure complex sensor, comprising:
coating a fabric with a graphene oxide;
reducing the graphene oxide coated on the fabric to form a graphene;
disposing carbon nanotubes on the fabric coated with the graphene; and
connecting an electrode to the fabric.

2. The method of claim 1, wherein the coating of the fabric with the graphene oxide comprises:
immersing the fabric in a first solution containing the graphene oxide; and
drying the fabric.

3. The method of claim 2, wherein the first solution comprises water.

4. The method of claim 1, wherein the reducing of the graphene oxide coated on the fabric comprises exposing the fabric coated with the graphene oxide to vapor of a reducing agent.

5. The method of claim 4, wherein the reducing agent is hydrazine.

6. The method of claim 4, wherein the exposing of the fabric coated with the graphene oxide to the vapor of the reducing agent is performed in a sealed chamber at a temperature of 70-80° C.

7. The method of claim 1, wherein the disposing of the carbon nanotubes on the fabric coated with the graphene comprises;
immersing the fabric coated with the graphene in a second solution containing carbon nanotubes; and
drying the fabric.

8. The method of claim 7, wherein the second solution comprises at least one of dimethylformamide (DMF) and dichlorobenzene (DCB).

9. The method of claim 7, wherein in the second solution, the carbon nanotubes are contained in an amount of 0.01-0.04 wt %.

10. The method of claim 1, wherein the fabric is cotton or wool.

11. The method of claim 1, after the connecting of the electrode to the fabric, further comprising performing a test,
wherein the performing of a test repeats several times at least one of:
applying a tensile force to the fabric and then stopping;
applying a compressive force to the fabric and then stopping; and
immersing the fabric in water and drying.

12. A strain-pressure complex sensor sensing a tensile force and a compressive force, comprising:
a fabric;
a graphene coated on the fabric; and
carbon nanotubes disposed on the fabric coated with the graphene.

13. The strain-pressure complex sensor of claim 12, wherein the fabric is cotton or wool.

14. The strain-pressure complex sensor of claim 12, further comprising:
a first electrode connected to one end of the fabric; and
a second electrode connected to the other end of the fabric.

15. The strain-pressure complex sensor of claim 12, wherein the graphene is a reduced graphene oxide.

16. The strain-pressure complex sensor of claim 12, wherein a part of the graphene is combined with oxygen.
